(19) United States
(12) Patent Application Publication
(10) Pub. No.: US 2024/0130088 A1
(43) Pub. Date: Apr. 18, 2024

(54) FLUID COOLING SYSTEM FOR COMPUTER CABINETS

(71) Applicant: POLINKE INTERNATIONAL CO., LTD., New Taipei City (TW)

(72) Inventor: CHUN-LIN CHENG, NEW TAIPEI CITY (TW)

(21) Appl. No.: 17/964,928

(22) Filed: Oct. 13, 2022

(51) Int. Cl. H05K 7/20

(52) U.S. Cl. CPC H05K 7/20763; H05K 7/20272; H05K 7/20281

(57) ABSTRACT

A fluid cooling system for computer cabinets includes a frame, a fluid circulation device, a chassis distributor, at least one mainboard end module, a cold fluid channel and a hot fluid channel. The frame is installed in the accommodation space in a movable pulling manner; the chassis distributor is installed on an outer side of the frame and connected to the fluid circulation device; the cold fluid channel and the hot fluid channel are provided for connecting the chassis distributor to the mainboard end module; and the chassis distributor includes a chassis cold exhaust pipe and a chassis heat pipe, such that a working fluid flowing through the mainboard end module can have a hot and cold separation, and finally return to the fluid circulation device to form a circulating flow.

### BACKGROUND

### Technical Field

The present disclosure relates to the field of a computer heating dissipation device, and more particularly relates to a fluid cooling system for computer cabinets capable of overcoming the issues of insufficient heat dissipation space and ventilation rate of the computer cabinet products, improving the hosts with a multi-module chassis that can be pulled out directly without the need of turning off the computer, and solving the problems including the disassembly and water leakage of traditional water-cooled systems.

### Description of Related Art

In traditional applications of a fluid cooling system such as the ones used for the computer cabinet of industrial servers, a pump is usually provided for pressurizing a working fluid (including fluid or liquid-state nitrogen or other atomizing gases used for cooling purposes, etc.) to divert the working fluid contained in a fluid box into different pipelines through a fluid cooling distributor, in order to cool and dissipate the heat generated by different heat sources in the servers. However, when the pipelines are connected to each other, the pressure of the working fluid is often affected by the length and diameter of the pipelines, which will cause a change of the flow. For example, if the distance of the pipeline is large, the flow will be decreased.

In addition, as to the common fluid cooling system for computer cabinets, the computer cabinets and different servers cannot be moved freely after the installation is completed, since most of the pumps, the fluid cold distributors and the pipelines adopt a fixed installation. Furthermore, a vast majority of the pipeline is exposed, such that the working fluid inside the pipelines cannot be cooled for certain during heat exchange, thereby lowering the cooling effect. In the past, different servers inside the computer cabinet were arranged in a vertically up and down direction, so that servers at the top and the bottom have the longest distance between them. When the pipelines are connected, the flows of the working fluid at the top and bottom servers with the longest distance apart from each other are different, and the cooling or heat dissipating effect will be uneven. Therefore, it is necessary to increase the power of the pump in order to overcome this issue. As a result, the installation cost will be increased. Obviously, improvements are required.

In view of the aforementioned problem, the present discloser has designed a fluid cooling system for computer cabinets, and the system uses a chassis distributor with a hot and cold separation function, and the cold and hot channels of the working fluid are separated, and can be quickly connected to a mainboard end module installed on the mainboard or device heat source module, and this system not only solves the problem of having insufficient cooling space and ventilation rate, but also improves the effect of pulling out the multi-module chassis host without the need of turning off the computer and solves the fluid leakage problem of the related art. In addition to the improved the heat dissipation efficiency, this disclosure also improves the using space flexibly, making this disclosure more practical.

### SUMMARY

Therefore, it is a primary objective of the present disclosure to provide a fluid cooling system for computer cabinets that includes a frame, a fluid circulation device, a chassis distributor, at least one mainboard end module, a cold fluid channel and a hot fluid channel, and the chassis distributor is installed onto the frame and movably pulled out for use. The chassis distributor includes a chassis cold exhaust pipe and a chassis heat pipe, and the chassis distributor is provided for separating the cold fluid channel and the hot fluid channel that are used for delivering a working fluid, and the hot and cold separation function can improve the heat dissipation efficiency. In addition, the chassis distributor can be connected quickly to the mainboard end module installed on a mainboard or device heat source module, and the chassis distributor is then connected to the fluid circulation device. This system not only solves the problem of having insufficient cooling space and ventilation rate, but also improves the effect of pulling out the multi-module chassis host without the need of turning off the computer and solves the fluid leakage problem of the related art, so as to achieve the effect of improving the heat dissipation efficiency and the convenience of use significantly.

To achieve the aforementioned and other objectives, this disclosure provides a fluid cooling system for computer cabinets which is installed in an accommodation space of the computer cabinets, and the fluid cooling system includes: a frame, having a carrying portion configured to be corresponsive to the accommodation space, and installable in the accommodation space by a pulling method; a fluid circulation device, installed on a side of the computer cabinet, and having a cold fluid input port and a hot fluid output port;

a chassis distributor, installed outside the frame, and comprising a chassis cold exhaust pipe and a chassis heat pipe, and the chassis cold exhaust pipe having a first cold fluid inlet and a plurality of cold fluid joints, and the chassis heat pipe having a first hot fluid outlet and a plurality of hot fluid joints, for connecting the first cold fluid inlet to the cold fluid input port, and connecting the first hot fluid outlet to the hot fluid output port; at least one mainboard end module, each being configured to be corresponsive to a mainboard or device heat source module to form an installation space, and installed onto the mainboard or device heat source module by a sliding friction method, and two sides of the installation space being bent inwardly to cover the mainboard or device heat source module to define a fixation, and the interior of the mainboard end module being configured to be corresponsive to the mainboard or device heat source module to form a flow space, and the flow space having a second cold fluid inlet and a second hot fluid outlet; a cold fluid channel, connected to the cold fluid joint and the second cold fluid inlet, to communicate with the flow space; and a hot fluid channel, connected to the hot fluid joint and the second hot fluid outlet, and communicated with the flow space; thereby, after being pressurized by the fluid circulation device, the fluid is sent to a chassis cold exhaust pipe of the chassis distributor for cooling to form a cold fluid, and the cold fluid is sent to the mainboard end module through the cold fluid channel to absorb the heat generated by in the flow space by the mainboard or device heat source module to form a hot fluid, and guide the hot fluid in the flow space into the chassis heat pipe, and then finally return the hot fluid to the fluid circulation device to define a circulating flow.

In an embodiment of this disclosure, the cold fluid joints and the hot fluid joints are fixed onto the chassis distributor by welding to achieve the effect of preventing fluid leakage. In addition, the chassis cold exhaust pipe and the chassis heat pipe of the chassis distributor are designed with a separate configuration to separate cold and hot working fluids and prevent possible adverse affection of the heat dissipation efficiency. In addition, the installation space of the mainboard end module of this disclosure is substantially U-shaped and has an elastic plate configured to be corresponsive to the mainboard or device heat source module, and an elastic restoring force of the elastic plate is provided for fixing the mainboard end module with the mainboard or device heat source module by a surface friction sliding contact.

In another embodiment, the frame of this disclosure has a movable pulling feature, and thus it can be applied to a fixed, a detachable chassis, a detachable blade chassis, or any other detachable chassis that requires heat dissipation, so as to improve its application significantly. In addition, the fluid circulation device of this disclosure has the functions of distributing fluid flow and controlling fluid pressure. Two embodiments are described below: 1. The fluid circulation device of this disclosure uses the fluid pressure control function to deliver the pressure by inputting the fluid and reflow and extract the hot fluid, in order to control the flow and distribute the pressure to the mainboard end module through the pipe size of the cold fluid channel and the hot fluid channel. 2. The fluid circulation device of this disclosure uses a fluid pressure control function of a natural pressure to control the flow and distribute the pressure to the mainboard end module through the pipe size of the cold fluid channel and the hot fluid channel, so as to improve the heat dissipation efficiency.

### BRIEF DESCRIPTION OF THE DRAWINGS

FIG. 1 is a schematic view of the structure of a preferred embodiment of this disclosure;

FIG. 2 is a hardware block diagram of a preferred embodiment of this disclosure;

FIG. 3 is a first schematic view showing the status of a preferred embodiment of this disclosure during use;

FIG. 4 is a second schematic view showing the status of a preferred embodiment of this disclosure during use; and

FIG. 5 is a third schematic view showing the status of a preferred embodiment of this disclosure during use.

### DESCRIPTION OF THE EMBODIMENTS

This disclosure will now be described in more detail with reference to the accompanying drawings that show various embodiments of this disclosure.

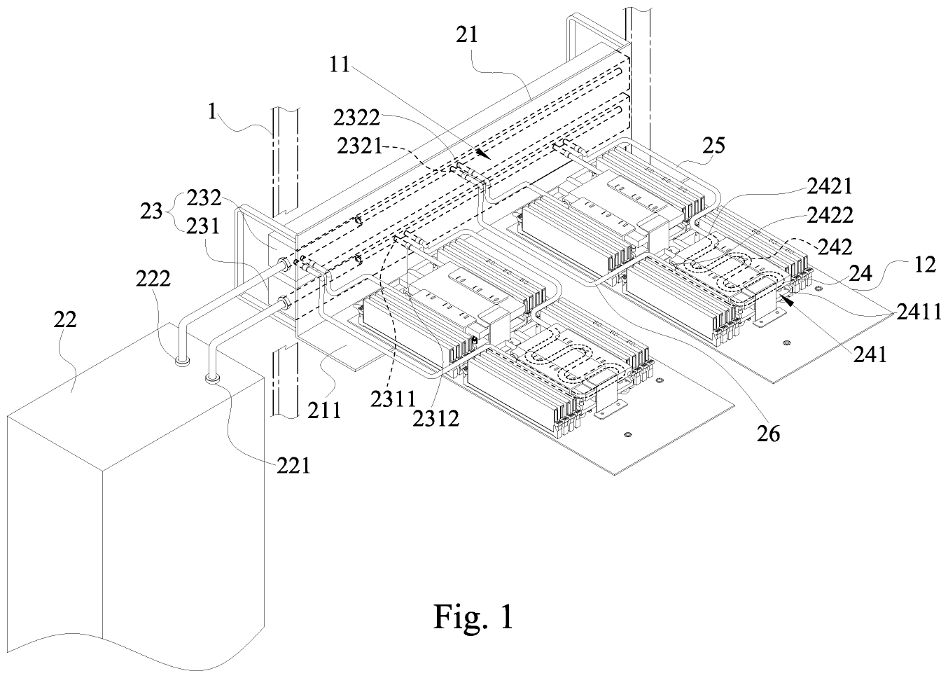

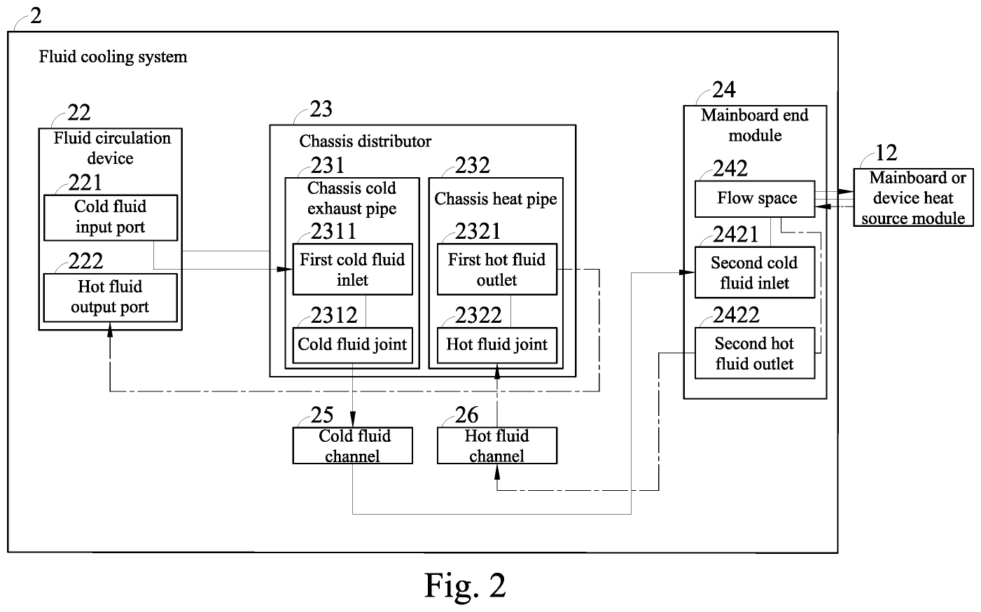

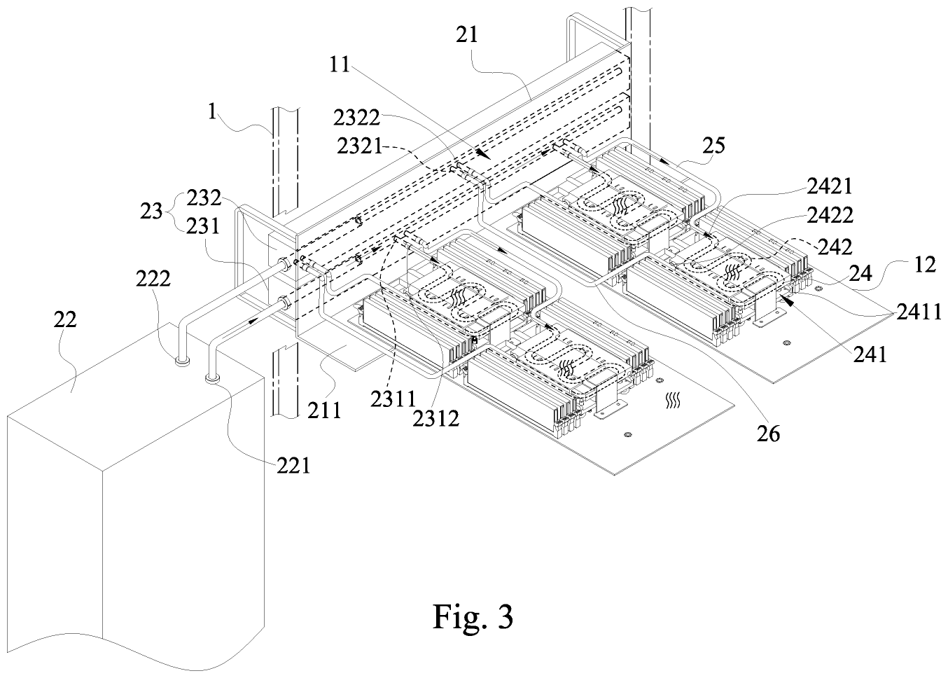

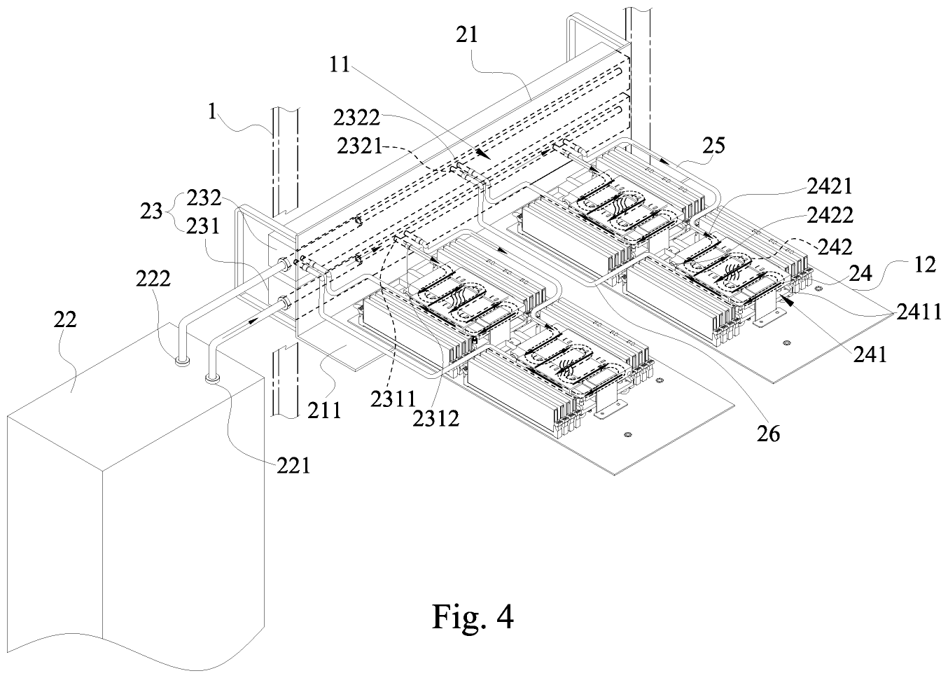

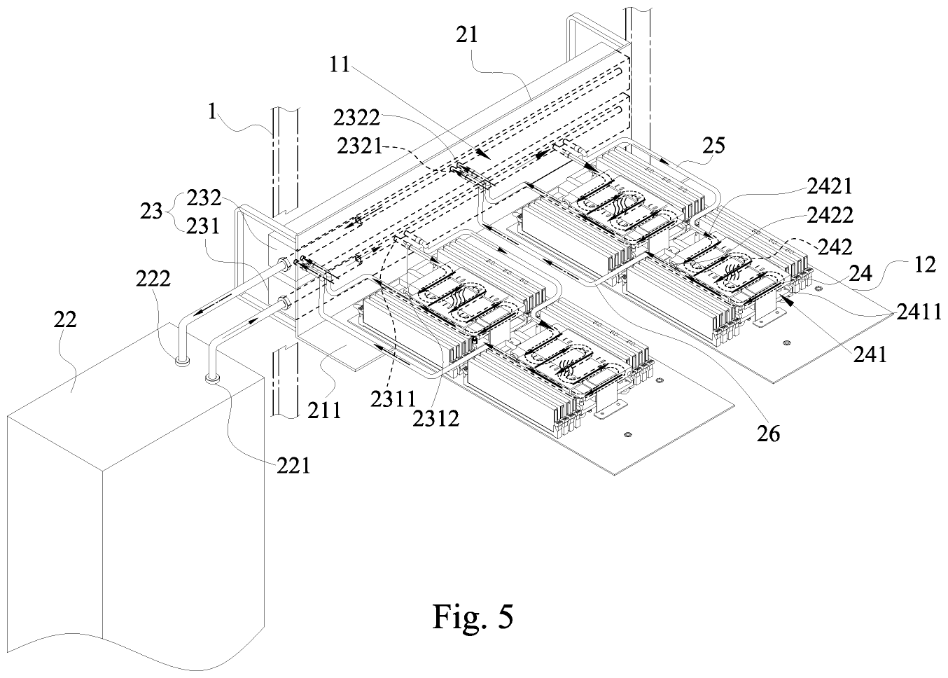

With reference to FIGS. 1, 2, and 3-5 for the schematic view and the hardware block diagram of a fluid cooling system for computer cabinets and various schematic views showing the status of the fluid cooling system during use in accordance with a preferred embodiment of this disclosure respectively, the fluid cooling system 2 of the computer cabinet 1 of this disclosure includes: a frame 21, a fluid circulation device 22, a chassis distributor 23, a plurality of mainboard end modules 24, a cold fluid channel 25 and a hot fluid channel 26, and the fluid cooling system 2 is installed in an accommodation space 11 of the computer cabinet 1.

Wherein, the frame 21 has a carrying portion 211 configured to be corresponsive to the accommodation space 11, and the frame 21 is installable in the accommodation space 11 by a pulling method. In addition, the frame 21 is one selected from a fixed chassis, a detachable chassis, a detachable blade chassis, or any other detachable chassis that requires heat dissipation.

The fluid circulation device 22 is installed on a side of the computer cabinet 1, and the fluid circulation device 22 includes a cold fluid input port 221 and a hot fluid output port 222. Further, the fluid circulation device 22 has the functions of distributing fluid flow and controlling fluid pressure. Two embodiments are described below: 1. The fluid circulation device 22 uses the fluid pressure control function to deliver the pressure by inputting the fluid and reflow and extract the hot fluid, in order to control the flow and distribute the pressure to the mainboard end module through the pipe size of the cold fluid channel 25 and the hot fluid channel 26. 2. The fluid circulation device 22 uses a fluid pressure control function of a natural pressure to control the flow and distribute the pressure to the mainboard end module 24 through the pipe size of the cold fluid channel 25 and the hot fluid channel 26.

The chassis distributor 23 is installed outside the frame 21, and the chassis distributor 23 includes a chassis cold exhaust pipe 231 and a chassis heat pipe 232, and the chassis cold exhaust pipe 231 has a first cold fluid inlet 2311 and a plurality of cold fluid joints 2312, and the chassis heat pipe 232 has a first hot fluid outlet 2321 and a plurality of hot fluid joints 2322, for connecting the first cold fluid inlet 2311 to the cold fluid input port 221, and connecting the first hot fluid outlet 2321 to the hot fluid output port 222. It is noteworthy that the cold fluid joints 2312 and the hot fluid joints 2322 are fixed onto the chassis distributor 23 by welding without the fluid leakage issue caused by unstable fixation, and the chassis cold exhaust pipe 231 and the chassis heat pipe 232 are designed with separate configurations.

Each mainboard end module 24 has an installation space 241 configured to be corresponsive to a mainboard or device heat source module 12 and installed onto the mainboard or device heat source module 12 by sliding friction, and two sides of the installation space 241 are bent inwardly to cover the mainboard or device heat source module 12 for a fixation, and the interior of the mainboard end module 24 has a flow space 242 configured to be corresponsive to the mainboard or device heat source module 12, and the flow space 242 has a second cold fluid inlet 2421 and a second hot fluid outlet 2422. In addition, the installation space 241 of the mainboard end module 24 of this disclosure is substantially U-shaped and has an elastic plate 2411 installed and configured to be corresponsive to the mainboard or device heat source module 12, and an elastic restoring force of the elastic plate 2411 is provided for fixing the mainboard end module 24 with the mainboard or device heat source module 12 by a surface friction sliding contact.

The cold fluid channel 25 is connected to the cold fluid joint 2312 and the second cold fluid inlet 2421 and communicated with the flow space 242.

The hot fluid channel 26 is connected to the hot fluid joint 2322 and the second hot fluid outlet 2422 and communicated with the flow space 242.

During use, the fluid cooling system 2 of this disclosure sends the working fluid to the chassis cold exhaust pipe 231 of the chassis distributor 23 for cooling to form a cold fluid after the working fluid is pressurized by the fluid circulation device 22, and sends the cold fluid to the mainboard end module 24 through the cold fluid channel 25, and absorbs the heat generated by the mainboard or device heat source module 12 in the flow space 242 to form a hot fluid, and guides the hot fluid in the flow space 242 into the chassis heat pipe 232, and finally returns the hot fluid to the fluid circulation device 22 to define a circulating flow. From this, we can know that the cold fluid channel 25 and the hot fluid channel 26 for sending the working fluid are separated by the chassis distributor 23, so as to achieve a hot and cold separation effect, which can improve the heat dissipation efficiency, and the chassis distributor 23 can be quickly connected to the mainboard end module 24 installed on the mainboard or device heat source module 12. The chassis distributor 23 connected to the fluid circulation device 22 not only solves the problems of having insufficient heat dissipation space and ventilation rate, but also allows the frame 21 to be pulled out directly without the need of turning off the computer, so as to improve the heat dissipation efficiency and the installation convenience during use.

What is claimed is:

1. A fluid cooling system for computer cabinets, installed in an accommodation space of the computer cabinets, comprising:
a frame, having a carrying portion configured to be corresponsive to the accommodation space, and installable in the accommodation space by a pulling method;
a fluid circulation device, installed on a side of the computer cabinet, and having a cold fluid input port and a hot fluid output port;
a chassis distributor, installed outside the frame, and comprising a chassis cold exhaust pipe and a chassis heat pipe, and the chassis cold exhaust pipe having a first cold fluid inlet and a plurality of cold fluid joints, and the chassis heat pipe having a first hot fluid outlet and a plurality of hot fluid joints, for connecting the first cold fluid inlet to the cold fluid input port, and connecting the first hot fluid outlet to the hot fluid output port;
at least one mainboard end module, each being configured to be corresponsive to a mainboard or device heat source module to form an installation space, and installed onto the mainboard or device heat source module by a sliding friction method, and two sides of the installation space being bent inwardly to cover the mainboard or device heat source module to define a fixation, and interior of the mainboard end module being configured to be corresponsive to the mainboard or device heat source module to form a flow space, and the flow space having a second cold fluid inlet and a second hot fluid outlet;
a cold fluid channel, coupled to the cold fluid joints and the second cold fluid inlet, and communicated with the flow space; and
a hot fluid channel, coupled to the hot fluid joints and the second hot fluid outlet, and communicated with the flow space;
thereby, after being pressurized by the fluid circulation device, fluid is sent to a chassis cold exhaust pipe of the chassis distributor for cooling to form a cold fluid, and the cold fluid is sent to the mainboard end module through the cold fluid channel to absorb the heat generated in the flow space by the mainboard or device heat source module to form a hot fluid, and guide the hot fluid in the flow space into the chassis heat pipe, and then finally return the hot fluid to the fluid circulation device to define a circulating flow.

2. The fluid cooling system for computer cabinets according to claim 1, wherein the cold fluid joints and the hot fluid joints are fixed onto the chassis distributor by welding.

3. The fluid cooling system for computer cabinets according to claim 1, wherein the chassis cold exhaust pipe and the chassis heat pipe of the chassis distributor are designed with a separate configuration.

4. The fluid cooling system for computer cabinets according to claim 1, wherein the installation space of the mainboard end module is substantially U-shaped, and comprises an elastic plate configured to be corresponsive to the mainboard or device heat source module, and an elastic restoring force of the elastic plate is provided for fixing the mainboard end module with the mainboard or device heat source module by a surface friction sliding contact.

5. The fluid cooling system for computer cabinets according to claim 1, wherein the frame is selected from a group consisting of a fixed chassis, a detachable chassis, a detachable blade chassis, and a detachable chassis that requires heat dissipation.

6. The fluid cooling system for computer cabinets according to claim 1, wherein the fluid circulation device has the functions of distributing fluid flow and controlling fluid pressure.

7. The fluid cooling system for computer cabinets according to claim 6, wherein the fluid circulation device uses the fluid pressure control function to deliver the pressure by inputting the fluid and reflow and extract the hot fluid, in order to control the flow and distribute the pressure to the mainboard end module through pipe size of the cold fluid channel and the hot fluid channel.

8. The fluid cooling system for computer cabinets according to claim 6, wherein the fluid circulation device uses a fluid pressure control function of a natural pressure to control the flow and distribute the pressure to the mainboard end module through pipe size of the cold fluid channel and the hot fluid channel.
